(19) United States
(12) Patent Application Publication
(10) Pub. No.: US 2021/0292501 A1
(43) Pub. Date: Sep. 23, 2021

(54) RELEASE HARD COATING, RELEASE FILM, AND PHOTOVOLTAIC MODULE

(71) Applicant: 3M INNOVATIVE PROPERTIES COMPANY, St. Paul, MN (US)

(72) Inventors: Junkang J. Liu, Woodbury, MN (US); Zhigang Yu, Shanghai (CN); Ta-Hua Yu, Woodbury, MN (US); Garry W. Lachmansingh, Plymouth, MN (US); Dongfeng Zheng, Beijing (CN)

(21) Appl. No.: 17/284,552

(22) PCT Filed: Oct. 23, 2019
(86) PCT No.: PCT/IB2019/059081

§ 371 Date: Apr. 12, 2021

(30) Foreign Application Priority Data
Oct. 26, 2018 (CN) 201811264920.9

(51) Int. Cl. C08J 7/046; C08J 7/18; C08K 3/22; C08K 3/26; C08K 3/30; C08K 3/36; C09D 171/02; C09D 133/12

(52) U.S. Cl. CPC C08J 7/046; C08J 2471/02; C08K 3/22; C08K 3/26; C08K 3/30; C08K 3/36; C09D 171/02; C09D 133/12; C08K 2003/2227; C08K 2003/2244; C08K 2003/2296; C08K 2003/265; C08K 2003/3063; C08K 2201/003; C08K 2201/011; C08J 2367/00; C08J 2433/12; C08J 7/18

(57) ABSTRACT

The present invention provides a release hard coating, comprising a bottom hard coating component and a top release coating component, wherein the bottom hard coating component comprises a crosslinked polymer matrix and nano-silica particles; and the top release coating component comprises a release polymer capable of having a grafting reaction with the bottom hard coating component. The release hard coating can be applied onto a substrate such as PET to resist sticky illegal advertisements and protect the substrate from wear.

### TECHNICAL FIELD

The present invention relates to a coating, and in particular to a release hard coating, a scratch-resistant release film, and a photovoltaic module.

### BACKGROUND

Renting vehicles, particularly shared bikes, is attracting increasingly more attention because the sharing contributes to low-carbon and is environmentally friendly, economic, and convenient. Users can quickly locate shared bikes nearby with cellphones and can rent the bikes after unlocking with the cellphones. Each shared bike is equipped with an electronic lock and a global positioning system (GPS) continuously powered with a solar panel secured in the bike basket. However, various illegal advertisement stickers are often stuck to these solar panels which in turn affects the normal function of these solar panels.

In the prior art, release coatings are widely applied in adhesion-resistant release paper because these coatings effectively release pressure sensitive adhesives; yet the release coatings are typically very soft and have poor abrasion resistance. On the other hand, hard coatings can provide hardness, and have good durability that prevents surface abrasion of the substrate; nevertheless, the hard coatings have a poor anti-adhesion property. In most situations, it is difficult to peel off release hard coatings from pressure sensitive adhesives.

A U.S. patent (U.S. Pat. No. 6,660,388) discloses an anti-soiling hard coating, comprising a substantially transparent substrate, a hard coating comprising inorganic oxide particulates dispersed in a binder matrix, and an anti-soiling layer comprising perfluorinated polyether. The film has very good anti-abrasion, anti-dirt, and anti-glare properties as well as very good interlayer adhesiveness and durability.

A U.S. patent (U.S. Pat. No. 4,472,480) discloses a low-surface-energy liner, comprising perfluoropolyether in-situ polymerized to an adhesive net that is adhered to a substrate. The low-surface-energy liner is particularly useful for the backing coating having a low attachment coefficient of a pressure sensitive adhesive tape.

A Chinese patent for invention (CN 102459378 B) discloses an anti-soiling composition, which is an anti-fouling composition containing a compound (A) having a perfluoropolyether group and an active energy ray-reactive group and inorganic particulates (B), wherein the composition comprises more than 20 parts by mass and less than 75 parts by mass of the compound (A) based on 100 parts by mass of solid ingredients therein.

A U.S. patent (U.S. Pat. No. 5,104,929) discloses a transparent abrasion-resistant coating, comprising colloidal silica particles dispersed in ethylenically unsaturated aliphatic and/or cycloaliphatic monomers, wherein the particle diameter of the silica particles is less than 100 nm, and the coating is highly useful for protecting plastic, wood, metal, and ceramic surfaces.

### SUMMARY

Regarding the fact that the prior art cannot simultaneously meet requirements of adhesion resistance, abrasion resistance, and hardness, the present invention provides a release hard coating, which can be applied on a substrate such as PET to resist sticky illegal advertisements and protect battery panels from impact and wear.

In order to achieve objectives of the invention, the release hard coating of the present invention comprises a bottom hard coating component and a top release coating component, wherein the bottom hard coating component comprises a crosslinked polymer matrix and nano-metal oxide particles; and the top release coating component comprises a release polymer capable of having a grafting reaction with the bottom hard coating component.

The nano-metal oxide particles can increase the hardness of the coating; and the addition of the crosslinked polymer matrix can form a net structure at the bottom of the coating that allows the coating to have a stronger and more stable mechanical structure, not easy to be damaged.

According to some embodiments of the present invention, the bottom hard coating component further comprises particulates with a particle diameter of between 0.5 μm and 100 μm.

After some research, the inventor found that after micron-sized particles are added into the bottom hard coating component and the coating is cured, the process not only generates foggy and frosting effects, the addition of the particulates also makes the coating surface rough, which in turn minimizes the contact area between the coating and pressure sensitive adhesive films (e.g., adhesive films of illegal advertisements), thereby providing a better release effect of the coating. Moreover, the particle diameter of the particulates has a certain influence on the technical effects of the present invention. The particle diameter of the particulates should not be excessively large. An excessively-large particle diameter will influence the stability of a film coating solution of the bottom hard coating component. Similarly, the particle diameter of the particulates should not be excessively small. An excessively-small particle diameter will not produce the foggy and frosting effects and will cause poor release effects. Therefore, when the particle diameter of the particulates is between 0.5 μm and 100 μm, better foggy and frosting effects can be obtained, and the release force can be improved.

According to some embodiments of the present invention, the particulates are selected from the group consisting of micron-sized polymer particles, micron-sized inorganic metal oxide particles, micron-sized metal salt particles, and combinations thereof.

Preferably, the micron-sized polymer particles are selected from the group consisting of polymethyl methacrylate (PMMA), polystyrene (PS), and combinations thereof.

Preferably, the micron-sized inorganic metal oxide particles are selected from the group consisting of silica, alumina titania, and combinations thereof.

Preferably, the micron-sized metal salt particles are selected from the group consisting of calcium carbonate, calcium sulfate, magnesium sulfate, and combinations thereof.

According to some embodiments of the present invention, the crosslinked polymer matrix comprises a multifunctional acrylate selected from the group consisting of trimethylolpropane triacrylate, tris(2-hydroxyethylisocyanurate) triacrylate, pentaerythritol triacrylate, pentaerythritol tetraacrylate, di-trimethylolpropane tetraacrylate, ethoxylated pentaerythritol tetraacrylate, dipentaerythritol pentaacrylate, and combinations thereof.

According to some embodiments of the present invention, the nano-metal oxide particles are selected from the group consisting of nano-silica particles, nano-alumina, nano-zirconia, nano-zinc oxide, and combinations thereof, wherein nano-silica particles are preferred. More preferably, the particle diameter of the nano-silica particles is less than 100 nm. Most preferably, the nano-silica particles have a particle diameter of less than 50 nm.

According to some embodiments of the present invention, the bottom hard coating component is subjected to photo-polymerization. A photoinitiator is added into the bottom hard coating component; and polymerization crosslinking and grafting reactions are initiated through the photoinitiator's absorption of ultraviolet quanta emitted from a UV lamp. Not only the bottom hard coating component can be cured through the above process, but the bottom hard coating component and the coating component can also be chemically bonded to firmly secure the top release coating component and prevent it from shedding.

According to some embodiments of the present invention, the release polymer is selected from the group consisting of fluorinated polyolefin, perfluoropolyether acrylate, polyfluorosilicone, and combinations thereof, wherein polyfluorosilicone is preferred.

According to some embodiments of the present invention, the thickness of the bottom hard coating component is between 1 μm and 250 μm. Preferably, the thickness is between 25 μm and 100 μm. The thickness of the bottom release coating component should not be too small. A thickness of less than 1 μm will influence the hardness and abrasion resistance; a too-think thickness will influence the curing of the coating.

According to some embodiments of the present invention, the thickness of the top release coating component is less than 500 nm. Preferably, the thickness is less than 100 nm. The thickness of the top release coating component is required to be very thin, thereby exhibiting the hardness and abrasion resistance of the coating.

The present invention further provides a release film comprising a substrate, wherein the substrate is coated on the surface thereof with the release hard coating of the present invention.

According to some embodiments of the present invention, the substrate includes at least one layer of polymer substrate selected from the group consisting of polyethylene terephthalate (PET), polyvinyl chloride (PVC), polymethyl methacrylate (PMMA), polyamide (PI), polyurethane (PU), and polycarbonate (PC).

According to some embodiments of the present invention, the substrate surface has a roughness of less than 100 μm.

According to some embodiments of the present invention, the release film has a peel force of 0.5 g/in to 2.0 g/in.

After an in-depth research, the present inventors have found that the surface roughness of both the bottom hard coating component and the substrate can influence the release effect. The rougher the surface of the bottom hard coating component, the better the release effect of the release film. Similarly, the rougher the substrate surface, the better the release effect of the release film. Therefore, the substrate surface can be treated by embossing to increase the roughness of the substrate surface, thereby reducing the contact area between the substrate and the adhesive and improving the release force. However, if the substrate surface is too rough, the structure of the release film will be unstable and the abrasion resistance will be degraded.

The present invention further provides a photovoltaic module comprising a photovoltaic cell, wherein a surface of the photovoltaic cell is coated with the release hard coating of the present invention or the release film of the present invention.

### BRIEF DESCRIPTION OF THE DRAWINGS

In order to make the above and other objects, features and advantages of the present invention more obvious and understandable, the present invention will be further explained below in combination with accompanying drawings and particular embodiments. A person skilled in the art would appreciate that the drawings are intended to schematically illustrate the preferred embodiments of the present invention, and the parts in the drawings may not be drawn to scale.

FIG. 1 is a structural representation of a release hard coating according to some specific embodiments of the present invention; and

FIGS. 2 to 3 are structural representations of a release film according to some specific embodiments of the present invention.

### DETAILED DESCRIPTION

Some embodiments in accordance with the present invention will be described below in more detail with reference to the accompanying drawings. It should be understood that, without departing from the scope and spirit of the present invention, a person skilled in the art would be able to envisage other various embodiments based on the teachings provided herein, and modify the same. Therefore, the embodiments set forth below are for illustration rather than limiting.

Unless otherwise indicated, all numbers used in this Description and the Claims for presenting size, amounts and physical properties of the features should be understood as being modified by the term “about”. Accordingly, unless indicated to the contrary, the numerical values set forth in this Description and the Claims are approximate values, and based on the teachings of the present invention, a person skilled in the art would be able to change such approximate values appropriately, so as to obtain desired properties. A numerical range represented by endpoints should include all numbers in the range, for example, the range 1 to 5 includes 1, 1.1, 1.3, 1.5, 2, 2.75, 3, 3.80, 4 and 5, etc.

Unless otherwise indicated, all materials used in the embodiments are commercially available industrial products.

### Release Hard Coating

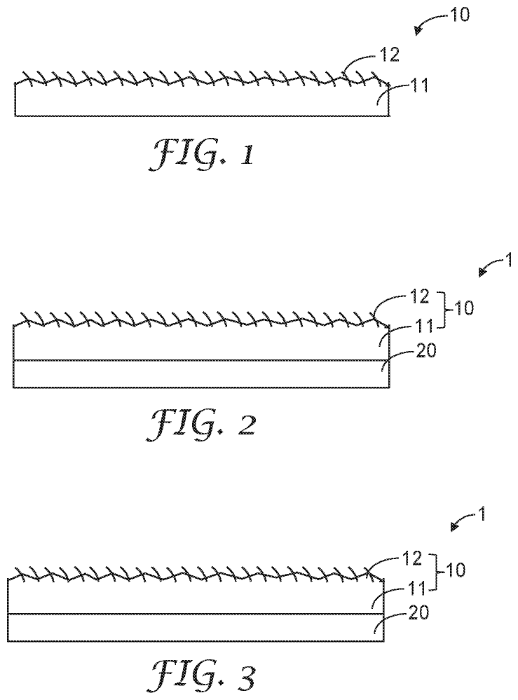

Some aspects of the present invention provide a release hard coating. As shown in FIG. 1, a release hard coating (10) comprises a bottom hard coating component (11) and a top release coating component (12), wherein the bottom hard coating component comprises a crosslinked polymer matrix and nano-metal oxide particles; and the top release coating component comprises a release polymer capable of having a grafting reaction with the bottom hard coating component (11).

### 1) Bottom Hard Coating Component

a. Nano-Silica

The nano-metal oxide particles may be preferably nano-silica particles, so as to increase the hardness of the coating. Preferably, the particle diameter of the nano-silica particles is less than 100 nm. More preferably, the particle diameter of the nano-silica particles is less than 50 nm. In the present invention, inorganic silica sols dissolved into water or water-alcohol are commercially available and may be selected from the group consisting of silica sols from E.I. duPont de Nemours and Co., Inc. (Wilmington, Del., USA) under the trade name of LUDOX SM; silica sols from Nyacol Co. (Ashand, Mass., USA) under the trade name of NYACOL; silica sols (average particle diameter 5 nm, pH 10.5, solid content 15%) from Ondea Nalco Chemical Co. (Oak Brook, Ill., USA) under the trade name of NALCO 2326; silica sols (average particle diameter 20 nm) from Ondea Nalco Chemical Co. under the trade name of NALCO 2327; silica sols (average particle diameter 75 nm) from Ondea Nalco Chemical Co. under the trade name of Nalco 2329K; silica sols from Ondea Nalco Chemical Co. under trade names of NALCO 1115 and NALCO 1130; and silica sols from Remet Corp. (Utica, N.Y., USA) under the trade name of REMASOL SP30. In addition to spherical nano-silica particles, non-spherical (i.e., acicular) silica particles can also be selected, which can be selected from the group consisting of: an aqueous suspension from Nissan Chemical Corp. (Tokyo, Japan) under the trade name of SNOWTEX-UP, the suspension mixture being composed of 20-21% (percentage by weight) of non-spherical silica, less than 0.35% (percentage by weight) of Na₂O, and water, wherein the acicular silica particles have an average diameter of 9 to 15 nm and a length of about 40 to 300 nm, and the suspension has a viscosity less than 100 mPa·s at 25° C., a pH value of about 9 to 10.5, and a specific weight of about 1.13 at 20° C.; an aqueous suspension from Nissan Chemical Corp. under the trade name of SNOWTEX-PS-S, the acicular silica particles in the suspension having the form of pearl strings and the suspension mixture being composed of 20-21% (percentage by weight) of silica in the form of pearl strings, less than 0.2% (percentage by weight) of Na₂O, and water, wherein the silica particles have a diameter of about 18 to 25 nm, a length of about 80 to 150 nm, and a particle size of 80 to 150 nm with a dynamic light scattering method, and the suspension has a viscosity less than 100 mPa·s at 25° C., a pH value of about 9 to 10.5, and a specific weight of about 1.13 at 20° C.; and an aqueous suspension from Nissan Chemical Corp. under the trade name of SNOWTEX-PS-M, the acicular silica particles in the suspension having the form of pearl strings and the suspension mixture being composed of 20-21% (percentage by weight) of silica in the form of pearl strings, less than 0.2% (percentage by weight) of Na₂O, and water, wherein the silica particles have a diameter of about 10 to 15 nm and a length of about 80 to 120 nm.

b. Crosslinked Polymer Matrix

The addition of the crosslinked polymer matrix can form a net structure at the bottom of the coating that allows the coating to have a stronger and more stable mechanical structure, not easy to be damaged. The crosslinked polymer matrix includes multifunctional acrylate, which may be selected from the group consisting of trimethylolpropane triacrylate from Surface Specialties (Smyrna, Ga., USA) under the trade name of TMPTA-N; tris(2-hydroxyethylisocyanurate) triacrylate from Sartomer Inc. (Exton, Pa., USA) under the trade name of SR368; pentaerythritol triacrylate from Sartomer Inc. under the trade name of SR444; pentaerythritol tetraacrylate acrylate from Sartomer Inc. under the trade name of SR295; di-trimethylolpropane tetraacrylate from Sartomer Inc. under the trade name of SR355; ethoxylated pentaerythritol tetraacrylate from Sartomer Inc. under the trade name of SR494; and dipentaerythritol pentaacrylate from Sartomer Inc. under the trade name of SR399.

c. Particulates

After some research, the inventor found that if some particulates like micron-sized polymer particles, micron-sized inorganic metal oxide particles, and micron-sized metal salt particles with a particle diameter between 0.5 μm and 100 μm are added into the bottom hard coating component, after the coating is cured, the process not only generates foggy and frosting effects, but also makes the coating surface rough, decreasing the contact area of the adhesive, thereby providing a better release effect of the coating. The particulate size has a certain influence on the performance of the coating; and if the particulate is excessively large, not only the release force of the coating will be reduced, which further influences the anti-adhesion performance, the frosting effect and the anti-reflection performance of the coating will also be influenced. Micron-sized metal oxide particles may be micrometer silica (average particle diameter 5-10 μm) from W.R. Grace (Columbia, Md., USA) under the trade name of Syloid. Micron-sized polymer particles or microbeads may be selected from the group consisting of microbead products from Sigma-Aldrich, Cospheric LLC (Santa Barbara, Calif., USA), J Color Chemicals, Spherotech (Lake Forest, Ill., USA), Sandun Industrial Park of Hangzhou in China, Microbeads (N-2021 Skedsmokorset, Norway), Bangs Laboratories (Fisher, Ind., USA), Polysciences Inc. (Warrington, Pa., USA), and Techpolymer (Mt Pleasant, Tenn., USA).

The thickness of the bottom hard coating component should not be excessively thin; and preferably the thickness is between 1 μm and 250 μm. The thickness of the bottom release coating component less than 1 μm will hinder curing of the release hard coating. Preferably, the thickness is between 25 μm and 100 μm.

### 2) Top Release Coating Component

Through the grafting reaction, the release polymer is combined together with the bottom hard coating component, which provides a good release effect. Preferably, the surface grafting release polymer may be selected from the group consisting of perfluoropolyether acrylate and polyfluorosilicone. Perfluoropolyether acrylate can be obtained according to the method as disclosed in U.S. Pat. No. 6,841,190; polyfluorosilicone is commercially available from Shin-Etsu Silicones of America, Inc. (Akron, Ohio, USA) under the trade name of X-70-201S.

The thickness of the top release coating component is very thin and preferably less than 100 nm. An increase in the thickness of the top release coating component will influence the binding force between the top release coating component and the bottom hard coating component, causing a portion of the top release coating component to shed and consequently affecting the release effect.

### Release Film

Some aspects of the present invention provide a release film. As shown in FIG. 2, the release film (1) comprises a substrate (20) coated on the surface thereof with the release hard coating (10) of the present invention. The release hard coating (10) comprises a bottom hard coating component (11) and a top release coating component (12). The substrate (20) may be a polymer substrate, such as polyethylene terephthalate (PET) from Mitsubishi Corp. under the trade name of Hostaphan® 3 SAC.

As shown in FIG. 3, the substrate (20) has an uneven and rougher surface after the embossing treatment. The roughness of the substrate surface has a certain influence on the release effect. The rougher the substrate surface is, the better release effect the release film would have. However, if the substrate surface is excessively rough, the abrasion resistance of the release film will be degraded and the structure thereof becomes unstable. Therefore, the roughness of the substrate surface is preferably less than 100 μm.

It is to be understood that FIG. 3 exemplarily shows the surface shape of the substrate after the embossing treatment. Those skilled in the art would understand that to achieve the same or similar technical effect, the substrate surface may be in other shapes.

### EXAMPLES

The examples and comparative examples set forth below will help understand the present invention; however, such examples and comparative examples are merely used to illustrate the present invention, and shall not be interpreted as limiting the scope thereof.

The raw materials used in the examples and comparative examples of the present invention are set forth in Table 1.

TABLE 1

| Raw material | Trade Name | Manufacturer |
|---|---|---|
| Polyethylene terephthalate, i.e., PET | Hostaphan 3SAC | Mitsubishi polyester Film, Inc. (Greer, |
| | | SC, USA) |
| Polyvinyl chloride film, i.e., PVC | Scotchcal 3630 | 3M Company (St Paul, MN, USA) |
| Pentaerythritol triacrylate, i.e., PTEA | SR444 | Sartomer Inc. (Exton, PA, USA) |
| Nano-silica particle (particle | Nalco 2327 | Ondea Nalco Chemical Co. (Oak |
| diameter: 20 nm) | | Brook, IL, USA) |
| Nano silica particle (particle | Nalco 2329 K | Ondea Nalco Chemical Co. (Naperville, |
| diameter: 75 nm) | | IL, USA) |
| Photoinitiator | IRGACURE 184 | Ciba Specialty Chemicals Inc. |
| | | (Tarrytown, NY, USA) |
| N,N-dimethylacrylamide, i.e., DMA) | 274135 | Sigma-Aldrich |
| | | (St. Louis, MO, USA) |
| 2,6-di-tertbutyl-4-methyl phenol | W218405 | Sigma-Aldrich |
| (butylated hydroxytoluene, i.e., | | (St. Louis, MO, USA) |
| BHT) | | |
| Thiodiphenylamine (phenothiazine) | P14831 | Sigma-Aldrich |
| | | (St. Louis, MO, USA) |
| Propylene glycol methyl ether | 268895 | Sigma-Aldrich |
| (1-methoxy-2-propanol) | | (St. Louis, MO, USA) |
| 3-(Methacryloxy) | SIM6487 | Gelest Inc. (Morrisville, PA, USA) |
| propyltrimethoxysilane | | |
| 3-(Methacryloyloxy) | | |
| propyltrimethoxy silane | | |
| Hindered amine light stabilizer | PROSTAB 5128 | Ciba Specialty Chemicals Inc. |
| (hindered amine nitroxide inhibitor) | | (Tarrytown, NY, USA) |
| Fluorinated solvent (fluorochemical | Novec Engineered | 3M Company (St Paul, MN, USA) |
| solvent) | Fluid HFE7600 | |
| Perfluoroether diacrylate | The structure disclosed | 3M Company (St Paul, MN, USA) |
| | in U.S. Patent U.S. Pat. | |
| | No. 6,841,190 | |
| Polyfluorosilicone (fluoroether | X-70-201S | Shin-Etsu Silicones of America, Inc. |
| silicone) | | (Akron, OH, USA) |
| Solvent (solvent for fluoroether | FS thinner | Shin-Etsu Silicones of America, Inc. |
| silicone) | | (Akron, OH, USA) |
| Polymethyl methacrylate particulates | PMPMS-1.4 | Cospheric LLC (Santa Barbara, |
| (PMMA particulates) | | California) |
| Pt catalyst | SIP6832.2 | Gelest Inc. (Morrisville, PA, USA) |
| Silicone release agent | SYL-OFF ™ SL 100 | Dow Corning (Midland, MI, USA) |
| Silicone crosslinker | SYL-OFF ™ SL 2 | Dow Corning (Midland, MI, USA) |
| Addition catalyst (addition cure | SYL-OFF ™ SL 3000 | Dow Corning (Midland, MI, USA) |
| catalyst) | | |

Some instruments employed in the Embodiments and Comparative Examples to perform preparation and testing in the present invention are shown in Table 2.

TABLE 2

| Instrument | Model | Manufacturer |
|---|---|---|
| Aging tester | QUV-SPRAY | Q-lab Corporation |
| Gravure coater | YS Gravure | Yasui Seiki |
| UV Lamp | H Bulb | Fusion |
| Peel tester | SP2000 | I MASS |
| Adhesive tape | 232 | 3M Company |
| Adhesive tape | 2003 | 3M Company |
| Steel wool | Scotch Brite | 3M Company |

### Preparation of Surface-Functionalized Nano-Silica Organic Solution

400 g of nano-silica particles (Nalco 2329K, average particle diameter of silica 75 nm) was injected into a 1 quart (0.95 L) reaction vessel. 450 g of propylene glycol methyl ether (268895), 9.2 g of 3-(methacryloyloxy) propyltrimethoxy silane (SIM6487), and 0.23 g of a water-soluble hindered amine light stabilizer (PROSTAB 5128, inhibitor content 5 wt %) were mixed and then added into the reaction vessel with stirring. The reaction vessel was sealed and heated at 80° C. for 16 h to form a surface functionalized silica dispersion. The mixed dispersion was further rotated and water evaporated to form an organic solution of 42.4 wt % nano-silica and 1-methoxy-2-propanol.

### Preparation of Hard Coating Mixture

### 1. Hard Coating Mixture Containing No Particulates

51.5 parts of curable adhesive pentaerythritol triacrylate (SR444) was poured into a reaction vessel and heated at about 49° C. 88 parts of nano-silica colloid (Nalco 2327, silica has an average particle diameter of 20 nm) was added into the reaction vessel containing pentaerythritol triacrylate (SR444). After mixing, the mixture contains 32.4 parts of nano-silica colloid. Then 15.6 parts of DMA (274135) was added thereto, and then 0.15 parts of BHT (W218405) and 0.02 parts of thiodiphenylamine (P14831) were mixed and added into the reaction vessel. At a condition of 100±20 mm Hg atmospheric pressure and 52° C.±2° C. temperature, the mixture was evaporated until most of the liquid was volatilized. The dry sample still contained a small amount of water left and was diluted with a mixed isopropanol/distilled water (14/1, solid content 50%) solution, and then further diluted with a mixed isopropanol/distilled water (14/1, solid content 25%) solution. A photoinitiator (IRGACURE 184) was added into the diluted sample to provide a photocurable mixture.

### 2. Hard Coating Mixture Containing Particulates

A functionalized silica organic solution was prepared according to the method of preparing a surface functionalized nano-silica organic solution disclosed in the present invention. 51.5 parts of curable adhesive pentaerythritol triacrylate (SR444) was poured into a reaction vessel and heated at about 49° C. 88 parts of functionalized nano-silica (the average particle diameter is 75 nm) was added into the reaction vessel containing pentaerythritol triacrylate (SR444), and after mixing, the mixture contained 32.4 parts of nano-silica colloid. Then 15.6 parts of DMA (274135) was added thereto, and then 0.15 parts of BHT (W218405) and 0.02 parts of thiodiphenylamine (P14831) were mixed and added into the reaction vessel. At a condition of 100±20 mm Hg atmospheric pressure and 52° C.±2° C. temperature, the mixture was evaporated until most of the liquid was volatilized. The dry sample still contained a small amount of water left and was diluted with a mixed isopropanol/distilled water (14/1, solid content 50%) solution, and then further diluted with a mixed isopropanol/distilled water (14/1, solid content 25%) solution. A photoinitiator (IRGACURE 184) was added into the diluted sample to provide a photocurable mixture. Finally, PMMA particles (PMPMS-1.4) with a particle diameter of 3 μm and an adhesive rate of 3% were added into the photocurable mixture.

### Example 1

A hard coating mixture containing no particulates was prepared according to the method of preparing a hard coating mixture (containing no particulates) disclosed in the present invention. The hard coating mixture was applied onto PET (Hostaphan 3SAC) with a #3 winding bar and oven-dried for 10 min at 50° C., placed under a UV lamp (H Bulb), and cured at a linear speed of 20 fpm with a 100% UV illumination.

A 0.7% perfluoropolyether acrylate (obtained from the structure as disclosed in U.S. Pat. No. 6,841,190) fluorinated solution (Novec HFE7600) was applied onto the above cured bottom hard coating component with a #5 winding bar, dried for 5 min in air, placed under a UV lamp (H Bulb), and cured at a linear speed of 20 fpm with a 25% UV illumination. Sample 1 was thus prepared.

### Example 2

A hard coating mixture containing no particulates was prepared according to the method of preparing a hard coating mixture (containing no particulates) disclosed in the present invention. The mixture was applied onto a polyvinyl chloride film (Scotchcal 3630) with a #3 winding bar and oven-dried for 10 min at 50° C., placed under a UV lamp (H Bulb), and cured at a linear speed of 40 fpm with a 100% UV illumination in a nitrogen environment.

A 0.7% perfluoropolyether acrylate (obtained from the structure as disclosed in U.S. Pat. No. 6,841,190) fluorinated solution (Novec HFE7600) was applied onto the above cured bottom hard coating component with a #5 winding bar, dried for 5 min in air, placed under a UV lamp (H Bulb), and cured at a linear speed of 20 fpm with a 25% UV illumination in a nitrogen environment. Sample 2 was thus prepared.

### Example 3

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried for 0.75 min in an oven at 70° C., placed under a UV lamp (H Bulb), and cured at a linear speed of 40 fpm with a 100% UV illumination in a nitrogen environment to finally form a frosted hard coating with a thickness of 5 μm.

A 0.5% perfluoropolyether acrylate (obtained from the structure as disclosed in U.S. Pat. No. 6,841,190) fluorinated solution (Novec HFE7600) was coated onto the above frosted hard coating with a #5 winding bar, dried for 5 min in air, and placed under a UV lamp (H Bulb) and cured at a linear speed of 20 fpm and a 25% UV illumination in a nitrogen environment to finally form a release coating with a thickness of 50 nm. Sample 3 was thus prepared.

### Example 4

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried for 0.75 min in an oven at 70° C., placed under a UV lamp (H Bulb), and cured at a linear speed of 40 fpm with a 100% UV illumination in a nitrogen environment to finally form a frosted hard coating with a thickness of 5 μm.

A 1% perfluoropolyether acrylate (obtained from the structure as disclosed in U.S. Pat. No. 6,841,190) fluorinated solution (Novec HFE7600) was applied onto the above frosted hard coating with a #5 winding bar, dried for 5 min in air, placed under a UV lamp (H Bulb), and cured at a linear speed of 20 fpm with a 25% UV illumination in a nitrogen environment to finally form a release coating with a thickness of 100 nm. Sample 4 was thus prepared.

### Example 5

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried for 0.75 min in an oven at 70° C., placed under a UV lamp (H Bulb), and cured at a linear speed of 40 fpm with a 100% UV illumination in a nitrogen environment to finally form a frosted hard coating with a thickness of 5 μm.

A 2% perfluoropolyether acrylate (obtained from the structure as disclosed in U.S. Pat. No. 6,841,190) fluorinated solution (Novec HFE7600) was applied onto the above frosted hard coating with a #5 winding bar, dried for 5 min in air, placed under a UV lamp (H Bulb), and cured at a linear speed of 20 fpm with a 25% UV illumination in a nitrogen environment to finally form a release coating with a thickness of 200 nm. Sample 5 was thus prepared.

### Example 6

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried in an oven at 70° C., placed under a UV lamp (H Bulb), and cured at a linear speed of 40 fpm with a 100% UV illumination in a nitrogen environment to finally form a frosted hard coating with a thickness of 5 μm.

A 0.7% perfluoropolyether acrylate (obtained from the structure as disclosed in U.S. Pat. No. 6,841,190) fluorinated solution (Novec HFE7600) was coated onto the above frosted hard coating with a reverse contact micro-gravure coater (triple helix) in a wet thickness of 0.5 mil at a linear coating speed of 30 ft/min, dried in an oven at 70° C., and placed under a UV lamp (H Bulb) and cured at a 100% UV illumination in a nitrogen environment. Sample 6 was thus prepared.

### Example 7

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried in an oven at 70° C., placed under a UV lamp (H Bulb), and cured at a linear speed of 40 fpm with a 100% UV illumination in a nitrogen environment to finally form a frosted hard coating with a thickness of 5 μm.

A 0.7% perfluoropolyether acrylate (obtained from the structure as disclosed in U.S. Pat. No. 6,841,190) fluorinated solution (Novec HFE7600) was coated onto the above frosted hard coating with a reverse contact micro-gravure coater (triple helix) in a wet thickness of 0.5 mil at a linear coating speed of 30 ft/min, dried in an oven at 70° C., and placed under a UV lamp (H Bulb) and cured at a 75% UV illumination in a nitrogen environment. Sample 7 was thus prepared.

### Example 8

A hard coating mixture containing particulates was prepared according to the method of preparing a hard coating mixture (containing particulates) disclosed in the present invention.

A photocurable mixture containing PMMA particles was applied onto PET (Hostaphan 3SAC) with a gravure coater, dried in an oven at 70° C., placed under a UV lamp (H Bulb), and cured at a linear speed of 40 fpm with a 100% UV illumination in a nitrogen environment to finally form a frosted hard coating with a thickness of 5 μm.

A 0.7% perfluoropolyether acrylate (obtained from the structure as disclosed in U.S. Pat. No. 6,841,190) fluorinated solution (Novec HFE7600) was coated onto the above frosted hard coating with a reverse contact micro-gravure coater (triple helix) in a wet thickness of 0.5 mil at a linear coating speed of 30 ft/min, dried in an oven at 70° C., and placed under a UV lamp (H Bulb) and cured at a 50% UV illumination in a nitrogen environment. Sample 8 was thus prepared.

### Example 9

On a prism film (obtained from the structure as disclosed in U.S. Patent US 2008/0291541) of linearly arranged prisms, a 0.5% perfluoropolyether acrylate (obtained from the method as disclosed in U.S. Pat. No. 6,841,190) fluorinated solution (Novec HFE7600) was applied onto the above frosted hard coating with a #5 winding bar, dried for 5 min in air, placed under a UV lamp (H Bulb), and cured at a linear speed of 20 fpm with a 25% UV illumination in a nitrogen environment to finally form a release coating with a thickness of 50 nm. Sample 9 was thus prepared.

### Example 10

On a prism film of linearly arranged prisms (obtained from the structure as disclosed in U.S. Patent US 2008/0291541), a 50 ppm platinum catalyst (SIP6832.2)-containing fluorosilicone solution (X-70-2015) was coated onto the above frosted hard coating with a #5 winding bar, and dried for 15 min in an oven at 80° C. Sample 10 was thus prepared.

### Example 11

On a prism film of linearly arranged prisms (obtained from the structure as disclosed in U.S. patent US 2008/0291541), a 50 ppm platinum catalyst (SIP6832.2)-containing 10% fluorosilicone solution (Fluorosilicone X-70-201S, solvent FS thinner) was coated onto the above frosted hard coating with a #5 winding bar, and dried for 15 min in an oven at 80° C. Sample 11 was thus prepared.

### Example 12

On a prism film of linearly arranged prisms (obtained from the structure as disclosed in U.S. Patent US 2008/0291541), a liquid mixture of 100 g of silicon release agent (SYL-OFF™ SL 100), 3 g of silicon crosslinker (SYL-OFF™ SL 2), and 0.05 g of an addition catalyst (SYL-OFF™ SL 3000) were coated onto the above frosted hard coating with a #5 winding bar, and dried for 15 min in an oven at 80° C. Sample 12 was thus prepared.

### Test Methods

In the present invention, the release film was evaluated for the anti-adhesion performance by using the “peel force test,” evaluated for the abrasion resistance by using the “scratch test,” evaluated for the durability by using the “aging test,” and evaluated for the hardness by using the “hardness test.”

### Peel Force Test

Samples were laminated with 3M 232 adhesive tapes, and tested with a peel tester according to the FTM 10 testing standards. Test results are recorded in Table 3-1. In this industry, it is generally agreed that a peel force value of less than 15 meets the anti-adhesion requirement; and when the peel force value is lower, it is considered that the sample has a better anti-adhesion performance.

### Scratch Test

Samples were laminated with 3M 2008 adhesive tapes, and tested with a peel tester according to the FTM 10 testing standards. Test results are recorded in Table 3-2. A 0# steel wool was allowed to rub back and forth for 100 cycles on the sample surface at a force of 200 g on Taber Abraser4000; and the scratched sample was laminated with the 3M 2008 adhesive tape. According to the FTM10 testing standards, the samples were tested with a peel tester. Test results are recorded in Table 3-2; and peel force values before and after the scratch were compared. If the sample meets the anti-adhesion requirement both before and after the scratch, it is considered that the sample has good abrasion resistance; and if the difference between the peel force values before and after the scratch is not great, it is considered that the sample has very good abrasion resistance.

### Aging Test

Samples were laminated with 3M 2008 adhesive tapes, and tested with a peel tester according to the FTM 10 testing standards. Test results are recorded in Table 3-3. According to the ASTM154-4 standards, the samples were placed into a UV aging oven (QUV Accelerated Weathering Tester, Q-lab Corporation) with the coated surface being facing outward and aged for 250 h. The sample was removed from the oven and observed for changes in the color and appearance; and the aged sample was laminated with a 3M 2008 adhesive tape. The samples were tested with a peel test according to FTM10 testing standards. Test results are recorded in Table 3-3. Peel force values before and after aging were compared. If the sample meets the anti-adhesion requirement both before and after the aging, it is considered that the sample has good durability; and if the difference between the peel force values before and after the aging is not great, it is considered that the sample has very good durability.

### Hardness Test

According to the GB/T6739-2006 testing standards, with a Mitubish test pencil (4H) of the standard hardness and an Elcometer3086 pencil hardness tester, the pencil core was allowed to scratch 5 to 10 mm on the sample surface at a pressure of 1 kg and an included angle between the pencil core and the sample surface of 45°, and the measurement was repeated 5 times at different locations. The hardness of the sample was determined by observing with eyes whether abrasion marks were present (or the number of graphite marks) on the sample surface. Test results are recorded in Table 3-4.

TABLE 3-1

| | Peel force value (g/in) |
|---|---|
| Example 1 | 10.1 |
| Example 2 | 7.4 |
| Example 3 | 3.7 |
| Example 4 | 2.3 |
| Example 5 | 1.6 |
| Example 6 | 1.8 |
| Example 7 | 1.2 |
| Example 8 | 0.8 |
| Example 9 | 0.5 |
| Example 10 | 0.5 |
| Example 11 | 3.5 |
| Example 12 | 4.7 |

TABLE 3-2

| | Peel force value | Peel force value |
|---|---|---|
| | before scratch (g/in) | after scratch (g/in) |
| Example 9 | 1.8 | 14.4 |
| Example 10 | 4.0 | 4.8 |

TABLE 3-3

| | Peel force value | Peel force value |
|---|---|---|
| | before aging (g/in) | after aging (g/in) |
| Example 8 | 4.8 | 6.5 |
| Example 9 | 1.8 | 13.9 |
| Example 10 | 4.0 | 4.4 |

TABLE 3-4

| | Hardness |
|---|---|
| Example 7 | 4H |

Based on the test results of Table 3-1, the release films according to some specific embodiments of the present invention have at least met the anti-adhesion performance requirements. Of those, the release films of Examples 3 to 12 have particularly good anti-adhesion performance. The test results of Table 3-2 indicate that the release films according to some specific embodiments of the present invention have good abrasion resistance. The test results of Table 3-4 indicate that the release films according to some specific embodiments of the present invention have good durability, which is especially the case with the release film of Embodiment 10. The release film of Example 10 not only has good anti-adhesion performance but also has a peel force value hardly changed after the scratch test or aging test. Both the abrasion resistance and durability thereof are excellent. In addition, the test results of Table 3-4 indicate that the release films according to some specific embodiments of the present invention may have a hardness of up to 4H.

The particular embodiments as set forth above illustrate merely the principle and effects of the present invention, rather than limit the same. A person skilled in the art would understand that any variations and modifications made thereto would fall within the scope of the present invention without departing from the spirit and scope thereof. The scope of the present invention should be defined by the appended Claims.

1. A release hard coating, comprising a bottom hard coating component and a top release coating component, wherein the bottom hard coating component comprises a crosslinked polymer matrix and nano-metal oxide particles; and the top release coating component comprises a release polymer capable of having a grafting reaction with the bottom hard coating component.

2. The release hard coating according to claim 1, wherein the bottom hard coating component further comprises particulates with a particle diameter between 0.5 μm and 100 μm.

3. The release hard coating according to claim 2, wherein the particulates are selected from the group consisting of micron-sized polymer particles, micron-sized inorganic metal oxide particles, micron-sized metal salt particles, and combinations thereof.

4. The release hard coating according to claim 3, wherein the micron-sized polymer particles are selected from the group consisting of polymethyl methacrylate (PMMA), polystyrene (PS), and combinations thereof.

5. The release hard coating according to claim 3, wherein the micron-sized inorganic metal oxide particles are selected from the group consisting of silica, alumina, titania, and combinations thereof.

6. The release hard coating according to claim 3, wherein the micron-sized metal salt particles are selected from the group consisting of calcium carbonate, calcium sulfate, magnesium sulfate, and combinations thereof.

7. The release hard coating according to claim 1, wherein the crosslinked polymer matrix comprises a multifunctional acrylate selected from the group consisting of trimethylolpropane triacrylate, tris(2-hydroxyethylisocyanurate) triacrylate, pentaerythritol triacrylate, pentaerythritol tetraacrylate, di-trimethylolpropane tetraacrylate, ethoxylated pentaerythritol tetraacrylate, dipentaerythritol pentaacrylate, and combinations thereof.

8. The release hard coating according to claim 1, wherein the nano-metal oxide particles are selected from the group consisting of nano-silica particles, nano-alumina, nano-zirconia, nano-zinc oxide, and combinations thereof.

9. The release hard coating according to claim 8, wherein the nano-metal oxide particles have a particle diameter of less than 100 nm.

10. The release hard coating according to claim 9, wherein the nano-metal oxide particles have a particle diameter of less than 50 nm.

11. The release hard coating according to claim 1, wherein the bottom hard coating component is subjected to photo-polymerization.

12. The release hard coating according to claim 1, wherein the release polymer is selected from the group consisting of fluorinated polyolefin, perfluoropolyether acrylate, polyfluorosilicone, and combinations thereof.

13. The release hard coating according to claim 1, wherein the thickness of the bottom hard coating component is between 1 μm and 250 μm.

14. The release hard coating according to claim 1, wherein the thickness of the bottom hard coating component is between 1 μm and 100 μm.

15. The release hard coating according to claim 1, wherein the thickness of the top release coating component is less than 500 nm.

16. The release hard coating according to claim 15, wherein the thickness of the top release coating component is less than 100 nm.

17. A release film, comprising a substrate, wherein a surface of the substrate is coated with the release hard coating according to claim 1.

18. The release film according to claim 17, wherein the substrate comprises at least one layer of polymer substrate selected from the group consisting of polyethylene terephthalate (PET), polyvinyl chloride (PVC), polymethyl methacrylate (PMMA), polyamide (PI), polyurethane (PU), and polycarbonate (PC).

19. The release film according to claim 17, wherein the substrate surface has a roughness of less than 100 μm.

20. The release film according to claim 17, wherein the release film has a peel force of 0.5 g/in to 2.0 g/in.
